(19) United States
(12) Patent Application Publication
(10) Pub. No.: US 2025/0089357 A1
(43) Pub. Date: Mar. 13, 2025

(54) SEMICONDUCTOR DEVICE AND METHOD OF MANUFACTURING SEMICONDUCTOR DEVICE

(71) Applicant: INSTITUTE OF MICROELECTRONICS, CHINESE ACADEMY OF SCIENCES, Beijing (CN)

(72) Inventors: Yongliang LI, Beijing (CN); Huaizhi LUO, Beijing (CN)

(21) Appl. No.: 18/822,794

(22) Filed: Sep. 3, 2024

(30) Foreign Application Priority Data
Sep. 8, 2023 (CN) 202311161632.1

(51) Int. Cl. H01L 27/092; H01L 21/28; H01L 21/8238; H01L 29/06; H01L 29/423; H01L 29/66; H01L 29/775; H01L 29/786

(52) U.S. Cl. CPC H10D 84/856; H01L 21/28211; H10D 30/014; H10D 30/43; H10D 30/6735; H10D 30/6757; H10D 62/121; H10D 64/017; H10D 84/0167; H10D 84/017; H10D 84/038

(57) ABSTRACT

The semiconductor device includes a semiconductor substrate; and a first gate-all-around transistor and a second gate-all-around transistor formed on the semiconductor substrate and spaced apart from each other in a direction parallel to a surface of the semiconductor substrate. Each of the first gate-all-around transistor and the second gate-all-around transistor includes at least one nanostructure layer between a source region and a drain region. The nanostructure layer in the first gate-all-around transistor and the nanostructure layer in the second gate-all-around transistor are integrally formed. A thickness of each part of each nanostructure layer in the first gate-all-around transistor in a length direction of the nanostructure layer is less than a thickness of a corresponding nanostructure layer in the second gate-all-around transistor. A thickness of a gate stack in the first gate-all-around transistor is greater than a thickness of a gate stack in the second gate-all-around transistor.

This application claims the benefit of priority to Chinese Patent Application No. 202311161632.1 filed on Sep. 8, 2023. The entire contents of this application are hereby incorporated herein by reference.

### TECHNICAL FIELD

The present disclosure relates to a field of semiconductor technology, and in particular to a semiconductor device and a method of manufacturing a semiconductor device.

### BACKGROUND

Compared with planar transistors and fin field-effect transistors, gate-all-around transistors have advantages such as relatively high gate control ability. Therefore, when transistors of different device types in an integrated circuit are all gate-all-around transistors, it is beneficial to improve operating performance of the integrated circuit.

### SUMMARY

In an aspect, the present disclosure provides a semiconductor device, including: a semiconductor substrate; and a first gate-all-around transistor and a second gate-all-around transistor formed on the semiconductor substrate and spaced apart from each other in a direction parallel to a surface of the semiconductor substrate. Each of the first gate-all-around transistor and the second gate-all-around transistor includes at least one nanostructure layer between a source region and a drain region. The nanostructure layer included in the first gate-all-around transistor and the nanostructure layer included in the second gate-all-around transistor are integrally formed. A thickness of each part of each nanostructure layer of the at least one nanostructure layer included in the first gate-all-around transistor in a length direction of the nanostructure layer included in the first gate-all-around transistor is less than a thickness of a corresponding nanostructure layer included in the second gate-all-around transistor. A thickness of a gate stack included in the first gate-all-around transistor is greater than a thickness of a gate stack included in the second gate-all-around transistor.

In another aspect, the present disclosure further provides a method of manufacturing a semiconductor device, including: providing a semiconductor substrate; and forming, on the semiconductor substrate, a first gate-all-around transistor and a second gate-all-around transistor spaced apart from each other in a direction parallel to a surface of the semiconductor substrate. Each of the first gate-all-around transistor and the second gate-all-around transistor includes at least one nanostructure layer between a source region and a drain region, and the nanostructure layer included in the first gate-all-around transistor and the nanostructure layer included in the second gate-all-around transistor are integrally formed. A thickness of each part of each nanostructure layer of the at least one nanostructure layer included in the first gate-all-around transistor in a length direction of the nanostructure layer included in the first gate-all-around transistor is less than a thickness of a corresponding nanostructure layer included in the second gate-all-around transistor. A thickness of a gate stack included in the first gate-all-around transistor is greater than a thickness of a gate stack included in the second gate-all-around transistor.

### BRIEF DESCRIPTION OF THE DRAWINGS

The accompanying drawings described here are intended to provide a further understanding of the present disclosure and constitute a part of the present disclosure. The illustrative embodiments and their explanations of the present disclosure are used to explain the present disclosure and do not constitute an improper limitation of the present disclosure, in the drawings:

FIG. 1 shows a 1^{st} schematic structural diagram of a semiconductor device in a manufacturing process provided by embodiments of the present disclosure;

FIG. 2 shows a 2^{nd} schematic structural diagram of a semiconductor device in a manufacturing process provided by embodiments of the present disclosure;

FIG. 3 shows a 3^{rd} schematic structural diagram of a semiconductor device in a manufacturing process provided by embodiments of the present disclosure;

FIG. 4 shows a 4^{th} schematic structural diagram of a semiconductor device in a manufacturing process provided by embodiments of the present disclosure;

FIG. 5 shows a 5^{th} schematic structural diagram of a semiconductor device in a manufacturing process provided by embodiments of the present disclosure;

FIG. 6 shows a 6^{th} schematic structural diagram of a semiconductor device in a manufacturing process provided by embodiments of the present disclosure;

FIG. 7 shows a 7^{th} schematic structural diagram of a semiconductor device in a manufacturing process provided by embodiments of the present disclosure;

FIG. 8 shows an 8^{th} schematic structural diagram of a semiconductor device in a manufacturing process provided by embodiments of the present disclosure;

FIG. 9 shows a 9^{th} schematic structural diagram of a semiconductor device in a manufacturing process provided by embodiments of the present disclosure;

FIG. 10 shows a 10^{th} schematic structural diagram of a semiconductor device in a manufacturing process provided by embodiments of the present disclosure;

FIG. 11 shows an 11^{th} schematic structural diagram of a semiconductor device in a manufacturing process provided by embodiments of the present disclosure;

FIG. 12 shows a 12^{th} schematic structural diagram of a semiconductor device in a manufacturing process provided by embodiments of the present disclosure;

FIG. 13 shows a 13^{th} schematic structural diagram of a semiconductor device in a manufacturing process provided by embodiments of the present disclosure;

FIG. 14A and FIG. 14B show 14^{th} and 15^{th} schematic structural diagrams of a semiconductor device in a manufacturing process provided by embodiments of the present disclosure, respectively;

FIG. 15A and FIG. 15B show 16^{th} and 17^{th} schematic structural diagrams of a semiconductor device in a manufacturing process provided by embodiments of the present disclosure, respectively;

FIG. 16A and FIG. 16B show 18^{th} and 19^{th} schematic structural diagrams of a semiconductor device in a manufacturing process provided by embodiments of the present disclosure, respectively;

FIG. 17A and FIG. 17B show 20^{th} and 21^{st} schematic structural diagrams of a semiconductor device in a manufacturing process provided by embodiments of the present disclosure, respectively;

FIG. 18A and FIG. 18B show 22^{th} and 23^{th} schematic structural diagrams of a semiconductor device in a manufacturing process provided by embodiments of the present disclosure, respectively;

FIG. 19A and FIG. 19B show 24^{th} and 25^{th} schematic structural diagrams of a semiconductor device in a manufacturing process provided by embodiments of the present disclosure, respectively;

FIG. 20A and FIG. 20B show 26^{th} and 27^{th} schematic structural diagrams of a semiconductor device in a manufacturing process provided by embodiments of the present disclosure, respectively;

FIG. 21A and FIG. 21B show 28^{th} and 29^{th} schematic structural diagrams of a semiconductor device in a manufacturing process provided by embodiments of the present disclosure, respectively; and

FIG. 22A and FIG. 22B show 30^{th} and 31^{st} schematic structural diagrams of a semiconductor device in a manufacturing process provided by embodiments of the present disclosure, respectively.

### DETAILED DESCRIPTION OF EMBODIMENTS

Hereinafter, embodiments of the present disclosure will be described with reference to accompanying drawings. However, it should be understood that these descriptions are only illustrative and not intended to limit scope of the present disclosure. In addition, in the description below, descriptions of well-known structures and techniques have been omitted to avoid unnecessary confusion with concepts of the present disclosure.

Various structural diagrams according to embodiments of the present disclosure are shown in the accompanying drawings. These drawings are not drawn to scale, and for purpose of clear expression, certain details have been enlarged and may have been omitted. Shapes of various regions and layers shown in the figures, as well as their relative sizes and positional relationships, are only illustrative. In practice, there may be deviations due to manufacturing tolerances or technical limitations, and those skilled in the art may design regions/layers with different shapes, sizes, and relative positions as desired in practice.

In the context of the present disclosure, when a layer/component is referred to as being located “on” another layer/component, the layer/component may be directly located on the another layer/component, or there may be an intervening layer/component between them. In addition, if a layer/component is located “above” another layer/component in a certain orientation, then when the orientation is reversed, the layer/component may be located “below” the another layer/component. In order to make technical problems to be solved by the present disclosure, technical solutions of the present disclosure, and beneficial effects of the present disclosure clearer, the following will provide further detailed explanation of the present disclosure in conjunction with the accompanying drawings and embodiments. It should be understood that the specific embodiments described here are only intended to explain the present disclosure and are not intended to limit the present disclosure.

In addition, terms “first” and “second” are used for descriptive purposes only and cannot be understood as indicating or implying relative importance or implicitly indicating the quantity of indicated technical features. Therefore, the features containing the terms “first” and “second” may explicitly or implicitly include one or more of these features. In the description of the present disclosure, “multiple” or “plurality of” means two or more, unless otherwise specified. The meaning of “several” refers to one or more, unless otherwise specified.

In the description of the present disclosure, it should be noted that unless otherwise specified and limited, the terms “installation”, “connected”, and “connection” should be understood in a broad sense. For example, it may be a fixed connection, a detachable connections, or an integrated connections; it may be a mechanical connection or an electrical connection; it may be a direct connection or an indirect connection through an intermediate medium; and it may be an internal connection of two components or an interaction between two components. For those skilled in the art, the specific meanings of the above terms in the present disclosure may be understood based on specific circumstances.

Compared with planar transistors and fin field-effect transistors, gate-all-around transistors have advantages such as higher gate control ability. Therefore, when transistors of different device types in an integrated circuit are all gate-all-around transistors, it is beneficial to improve operating performance of the integrated circuit.

In practice, gate stacks of different transistors in the integrated circuit usually have different thicknesses so as to meet respective operating requirements. For example, the integrated circuit has an input/output (I/O) device and a core device. The input/output device is mainly used to achieve an input/output function between a chip in the integrated circuit and a peripheral circuit. As a higher operating voltage (generally, 1.8V, 2.5V, 3.3V or 5V, etc.) needs to be applied to the input/output device, the input/output device has a gate dielectric layer with a greater thickness. The core device is a device used in the chip and mainly used to perform logical operations in the chip. Based on this, as the chip includes a large number of core devices, a lower operating voltage (generally, 1.0V or 1.2V, etc.) is usually applied to the core devices in order to achieve the purpose of saving power consumption and increasing computing speed. Therefore, the core device has a gate dielectric layer with a smaller thickness.

In view of the above, if gate stacks of different gate-all-around transistors in the integrated circuit have different thicknesses, it is difficult to achieve the integration of the device structures which are all the gate-all-around transistors as described above using existing manufacturing methods, and it is also difficult to improve the operating performance of the gate-all-around transistors as described above. For example, the following takes the manufacturing of a core device and an input/output device on a same substrate as an example for illustration. Based on same channel material layers and same sacrificial material layers, channels are formed in a core device region and an I/O device region on the same substrate, respectively. Next, a gate dielectric layer (with a smaller thickness) surrounding a periphery of the channel of the core device is formed in the core device region of the substrate, and a gate dielectric layer (with a greater thickness) surrounding a periphery of the channel of the input/output device is formed in the I/O device region of the substrate. As a distance between adjacent nanowires/sheets only meets the structural requirements of the core device, for the input/output device, after forming a thicker gate dielectric layer, a small void between nanowires/sheets is filled by the gate dielectric layer or only a small gate formation space is retained between the nanowires/sheets. Then, it is impossible to form a metal gate of the input/output device that meets the operating requirements in the void or small gate formation space described above, thereby causing “pinch-off” phenomenon between adjacent nanowires/sheets in the I/O device region, which affects electrical performance of the input/output device formed in the I/O device region. Then, it is difficult to achieve the integration of the core device and the input/output device whose device structures are all gate-all-around transistors, and the operating performance of the input/output device is reduced.

Embodiments of the present disclosure provide a semiconductor device and a method of manufacturing a semiconductor device. In the semiconductor device provided in embodiments of the present disclosure, a first gate-all-around transistor and a second gate-all-around transistor are formed on a semiconductor substrate and spaced apart from each other in a direction parallel to a surface of the semiconductor substrate, and a nanostructure layer between a source region of the first gate-all-around transistor and a drain region of the first gate-all-around transistor and a nanostructure layer between a source region of the second gate-all-around transistor and a drain region of the second gate-all-around transistor are integrally formed. A thickness of each part of the nanostructure layer included in the first gate-all-around transistor in a length direction of the nanostructure layer included in the first gate-all-around transistor is less than a thickness of a corresponding nanostructure layer included in the second gate-all-around transistor. On the premise of solving the problem of poor compatibility between different gate-all-around transistors which have gate stacks of different thicknesses, the operating performances of the gate-all-around transistors are improved.

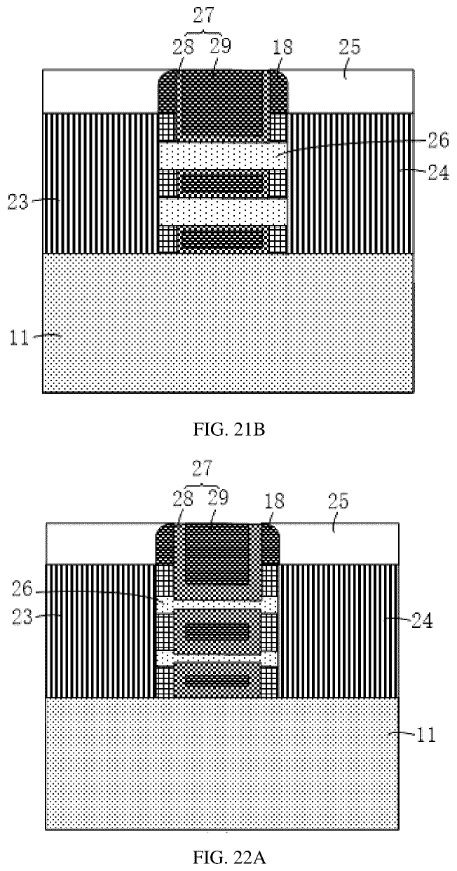

For example, in a first aspect, as shown in FIG. 21A and FIG. 21B, the semiconductor device provided by embodiments of the present disclosure includes a semiconductor substrate 11, and a first gate-all-around transistor and a second gate-all-around transistor formed on the semiconductor substrate 11 and spaced apart from each other in a direction parallel to a surface of the semiconductor substrate 11. Each of the first gate-all-around transistor and the second gate-all-around transistor includes at least one nanostructure layer 26 between a source region 23 and a drain region 24. The nanostructure layer 26 included in the first gate-all-around transistor and the nanostructure layer 26 included in the second gate-all-around transistor are integrally formed. A thickness of each part of each nanostructure layer 26 included in the first gate-all-around transistor in a length direction of that nanostructure layer 26 included in the first gate-all-around transistor is less than a thickness of a corresponding nanostructure layer 26 included in the second gate-all-around transistor, and a thickness of a gate stack 27 included in the first gate-all-around transistor is greater than a thickness of a gate stack 27 included in the second gate-all-around transistor.

The above semiconductor substrate may be a silicon substrate, a germanium silicon substrate, a germanium substrate, or a silicon on insulator, etc., on which no structure is formed.

Alternatively, the semiconductor substrate may also be the semiconductor substrate on which some structures are formed. For example, the structure formed on the semiconductor substrate may be determined according to practical application scenes, and there is no specific limitation here. For example, when applying the semiconductor device provided by embodiments of the present disclosure to a second or higher semiconductor device layer in the integrated circuit, the semiconductor substrate includes a semiconductor base substrate, at least one semiconductor device layer below the semiconductor device provided by embodiments of the present disclosure, and an interlayer dielectric layer that separates different semiconductor device layers.

For the first gate-all-around transistor and the second gate-all-around transistor described above, in terms of formation position, embodiments of the present disclosure do not impose specific limitations on the formation positions of the first gate-all-around transistor and the second gate-all-around transistor on the semiconductor substrate, as long as the first gate-all-around transistor and the second gate-all-around transistor are spaced apart from each other in the direction parallel to the surface of the semiconductor substrate.

In terms of conductivity type, the conductivity types of the first gate-all-around transistor and the second gate-all-around transistor may be the same. In this case, both the first gate-all-around transistor and the second gate-all-around transistor may be N-type gate-all-around transistors or P-type gate-all-around transistors. Alternatively, the conductivity types of the first gate-all-around transistor and the second gate-all-around transistor may also be opposite. For example, the first gate-all-around transistor may be an N-type gate-all-around transistor, and the second gate-all-around transistor may be a P-type gate-all-around transistor. For another example, the first gate-all-around transistor may be a P-type gate-all-around transistor, and the second gate-all-around transistor may be an N-type gate-all-around transistor.

In terms of structure, the first gate-all-around transistor may include a source region, a drain region, at least one nanostructure layer, and a gate stack. The at least one nanostructure layer included in the first gate-all-around transistor is located between the source region and the drain region, and two ends of each nanostructure layer in the length direction of that nanostructure layer are in contact with the source region and the drain region, respectively. The gate stack in the first gate-all-around transistor includes a gate dielectric layer and a gate electrode. The gate dielectric layer surrounds a periphery of at least part region of each nanostructure layer in the length direction of that nanostructure layer, and the gate electrode is formed on the gate dielectric layer. In some cases, as shown in FIG. 21A, the first gate-all-around transistor may further include a gate spacer 18. The gate spacer 18 included in the first gate-all-around transistor is located on two sides of the gate stack 27 in a length direction of the gate stack 27. The gate spacer 18 included in the first gate-all-around transistor extends on edge parts of the nanostructure layer 26 on two sides of the nanostructure layer 26 included in the first gate-all-around transistor in the length direction of the nanostructure layer 26.

The second gate-all-around transistor may include a source region, a drain region, at least one nanostructure layer, and a gate stack. In some cases, as shown in FIG. 21B, the second gate-all-around transistor may further include a gate spacer 18. The positional relationship between different structures included in the second gate-all-around transistor may refer to the positional relationship between corresponding structures in the first gate-all-around transistor described above, which will not be repeated here.

In addition, each of the first gate-all-around transistor and the second gate-all-around transistor described above may include one nanostructure layer. Alternatively, each of the first gate-all-around transistor and the second gate-all-around transistor described above may include at least two nanostructure layers spaced apart from each other in a thickness direction of the semiconductor substrate. The number of the nanostructure layers included in the first gate-all-around transistor is the same as the number of the nanostructure layers included in the second gate-all-around transistor, and a central axis of each nanostructure layer in the first gate-all-around transistor coincides with a central axis of the corresponding nanostructure layer in the second gate-all-around transistor.

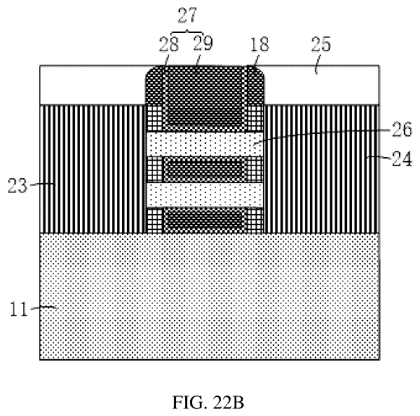

It should be noted that, the thickness of each part of each nanostructure layer included in the first gate-all-around transistor in a length direction of that nanostructure layer included in the first gate-all-around transistor is less than the thickness of the corresponding nanostructure layer included in the second gate-all-around transistor. As shown in FIG. 21A and FIG. 21B and FIG. 22A and FIG. 22B, a thickness of a part of each nanostructure layer 26 included in the first gate-all-around transistor surrounded by the gate stack 27 is less than a thickness of the corresponding nanostructure layer 26 included in the second gate-all-around transistor, and when each of the first gate-all-around transistor and the second gate-all-around transistor further includes the gate spacer 18, a thickness of a part of the nanostructure layer 26 included in the first gate-all-around transistor below the gate spacer 18 is also less than the thickness of the corresponding nanostructure layer 26 included in the second gate-all-around transistor.

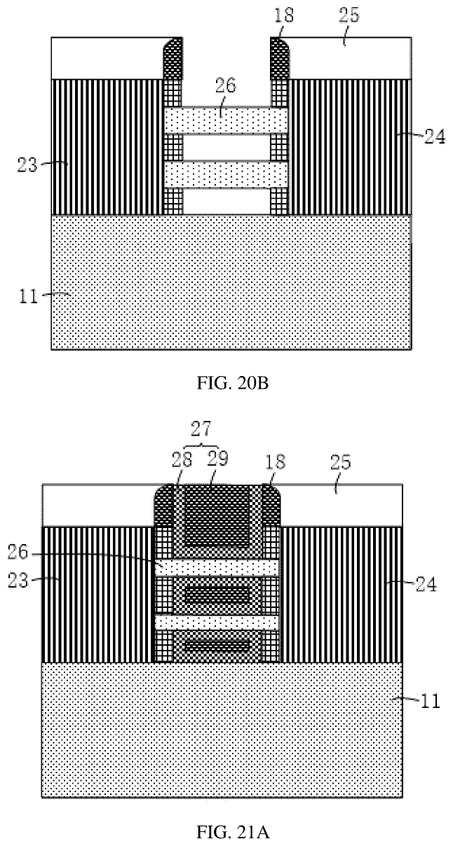

For example, as shown in FIG. 21A, the thickness of each part of each nanostructure layer 26 included in the first gate-all-around transistor in the length direction of that nanostructure layer 26 may be the same. Alternatively, as shown in FIG. 22A, a thickness of a middle part of each nanostructure layer 26 included in the first gate-all-around transistor in the length direction of that nanostructure layer 26 may be less than a thickness of each of edge parts of that nanostructure layer 26 on two sides of that nanostructure layer 26. When the first gate-all-around transistor further includes a gate spacer 18, and the gate spacer 18 extends on the edge parts of the nanostructure layer 26 on two sides of the nanostructure layer 26 included in the first gate-all-around transistor in the length direction of the nanostructure layer 26, as the gate stack 27 included in the first gate-all-around transistor surrounds a periphery of the middle part of each nanostructure layer 26 in the length direction of that nanostructure layer 26, the thickness of the middle part of each nanostructure layer 26 included in the first gate-all-around transistor in the length direction of that nanostructure layer 26 is less than the thickness of each of the edge parts of that nanostructure layer 26 on two sides of that nanostructure layer 26. In the practical manufacturing process, it is possible to further improve a height of a void for filling the gate stack 27 included in the first gate-all-around transistor, so as to ensure that the thickness of the gate dielectric layer 28 and the thickness of the gate electrode 29 in the first gate-all-around transistor meet the operating requirements, thereby improving the yield of the first gate-all-around transistor. For example, this may be achieved by manufacturing a part of the gate dielectric layer 28 included in the first gate-all-around transistor by using thermal oxidation process or other processes after releasing the nanostructure layer 26 included in the first gate-all-around transistor, as shown in FIG. 20A and FIG. 22A. As an exposed part of the nanostructure layer 26 will be consumed when forming the part of the gate dielectric layer 28 by using thermal oxidation process, the thickness of the middle part of the nanostructure layer 26 in the first gate-all-around transistor in the length direction of the nanostructure layer 26 is less than the thickness of each of the edge parts of the nanostructure layer 26 on two sides of the nanostructure layer 26 in the first gate-all-around transistor. After releasing the nanostructure layer 26 included in the first gate-all-around transistor, if the gate dielectric layer 28 included in the first gate-all-around transistor is formed by atomic layer deposition or other methods that do not consume the exposed part of the nanostructure layer 26, then the thickness of each part of the nanostructure layer 26 in the first gate-all-around transistor in the length direction of the nanostructure layer 26 in the first gate-all-around transistor is the same.

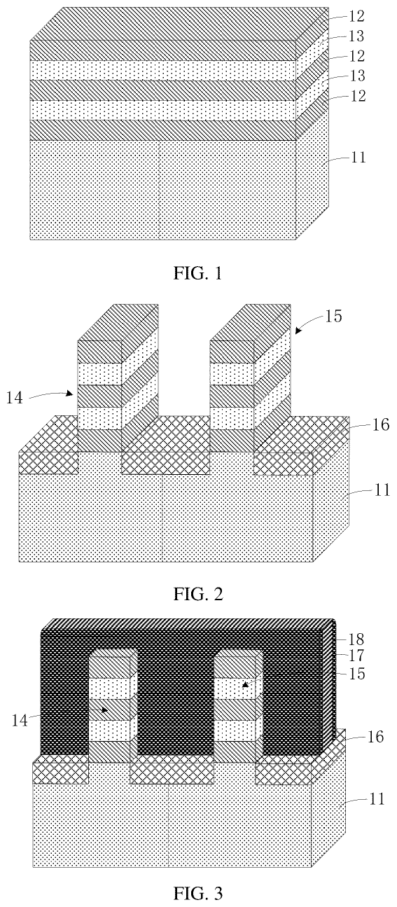

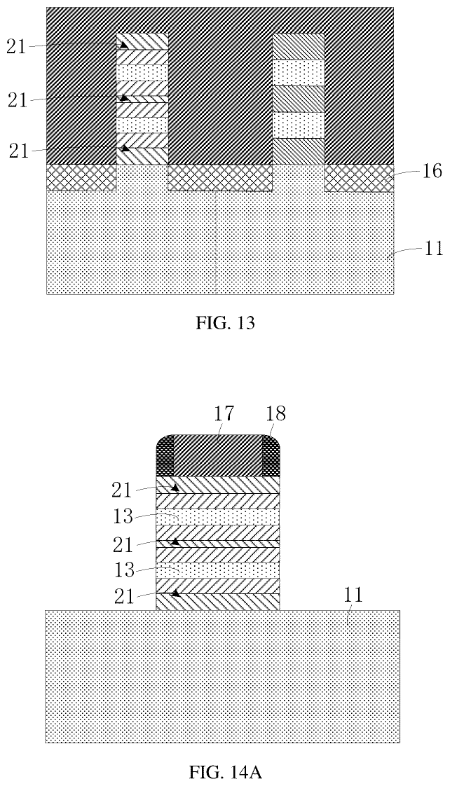

As for a width of the nanostructure layer included in the first gate-all-around transistor and a width of the nanostructure layer included in the second gate-all-around transistor, as shown in FIG. 13, the width of the nanostructure layer 26 included in the first gate-all-around transistor may be equal to the width of the nanostructure layer 26 included in the second gate-all-around transistor. In this case, as shown in FIG. 1 to FIG. 22A and FIG. 22B, in a case that a width of a first fin portion 14 used for manufacturing the nanostructure layer 26 included in the first gate-all-around transistor is equal to a width of a second fin portion 15 used for manufacturing the nanostructure layer 26 included in the second gate-all-around transistor, if the width of the nanostructure layer 26 included in the first gate-all-around transistor is equal to the width of the nanostructure layer 26 included in the second gate-all-around transistor, it means that in the process of manufacturing the semiconductor device, only the thickness of the nanostructure layer 26 included in the first gate-all-around transistor in a thickness direction of the semiconductor substrate 11 has been reduced relative to the thickness of the nanostructure layer 26 included in the second gate-all-around transistor in the thickness direction of the semiconductor substrate 11, while the width of the nanostructure layer 26 included in the first gate-all-around transistor and the width of the nanostructure layer 26 included in the second gate-all-around transistor have not been changed.

Alternatively, the width of the nanostructure layer included in the first gate-all-around transistor may also be greater than or less than the width of the nanostructure layer included in the second gate-all-around transistor, as long as the width of the nanostructure layer included in the first gate-all-around transistor is equal to an initial width of the first fin portion used for manufacturing the nanostructure layer included in the first gate-all-around transistor.

In terms of materials, materials of the source regions, drain regions, and nanostructure layers included in the first gate-all-around transistor and the second gate-all-around transistor are semiconductor materials such as silicon, germanium silicon, or germanium. A material of the nanostructure layer included in the first gate-all-around transistor is the same as a material of the nanostructure layer included in the second gate-all-around transistor. A material of the source region included in the first gate-all-around transistor may be the same as a material of the source region included in the second gate-all-around transistor, and a material of the drain region included in the first gate-all-around transistor may be the same as a material of the drain region included in the second gate-all-around transistor. Alternatively, a material of the source region included in the first gate-all-around transistor may be different from a material of the source region included in the second gate-all-around transistor, and a material of the drain region included in the first gate-all-around transistor may be different from a material of the drain region included in the second gate-all-around transistor. In addition, a material of the gate dielectric layer included in each of the first gate-all-around transistor and the second gate-all-around transistor described above may include a dielectric material such as HfO₂, ZrO₂, TiO₂ or Al₂O₃. The material of the gate dielectric layer included in the first gate-all-around transistor may also include a material such as silicon oxide. A material of the gate electrode included in each of the first gate-all-around transistor and the second gate-all-around transistor may include a conductive material such as TiN, TaN or TiSiN.

In terms of operating types, embodiments of the present disclosure do not impose specific limitations on operating types of the first gate-all-around transistor and the second gate-all-around transistor, as long as the thickness of the gate stack included in the first gate-all-around transistor is greater than the thickness of the gate stack included in the second gate-all-around transistor. The thickness of the gate stack included in the first gate-all-around transistor being greater than the thickness of the gate stack included in the second gate-all-around transistor may refer to that: only the thickness of the gate dielectric layer included in the first gate-all-around transistor is greater than the thickness of the gate dielectric layer included in the second gate-all-around transistor; alternatively, only the thickness of the gate electrode included in the first gate-all-around transistor is greater than the thickness of the gate electrode included in the second gate-all-around transistor; alternatively, the thickness of the gate dielectric layer included in the first gate-all-around transistor is greater than the thickness of the gate dielectric layer included in the second gate-all-around transistor, and the thickness of the gate electrode included in the first gate-all-around transistor is greater than the thickness of the gate electrode included in the second gate-all-around transistor.

For example, the first gate-all-around transistor described above may be an input/output gate-all-around transistor, and the thickness of the gate dielectric layer included in the first gate-all-around transistor is greater than the thickness of the gate dielectric layer included in the second gate-all-around transistor.

From the above content, it may be seen that as shown in FIG. 21A and FIG. 21B, the first gate-all-around transistor and the second gate-all-around transistor in the semiconductor device provided by embodiments of the present disclosure are formed on the semiconductor substrate 11 and spaced apart from each other in the direction parallel to the surface of the semiconductor substrate 11. Moreover, as shown in FIG. 1 to FIG. 21A and FIG. 21B, the nanostructure layer 26 between the source region 23 and the drain region 24 in the first gate-all-around transistor and the nanostructure layer 26 between the source region 23 and the drain region 24 in the second gate-all-around transistor are integrally formed. Based on this, in the practical manufacturing process, the nanostructure layer 26 included in the first gate-all-around transistor and the nanostructure layer 26 included in the second gate-all-around transistor may be manufactured based on a same stack of a channel layer 13 and sacrificial layers 12 alternately arranged, and there is no need to use different channel layers 13 to respectively manufacture the nanostructure layer 26 included in the first gate-all-around transistor and the nanostructure layer 26 included in the second gate-all-around transistor due to different thicknesses of the nanostructure layers 26 in the first gate-all-around transistor and the second gate-all-around transistor, thereby simplifying the process of manufacturing the semiconductor device, and reducing the manufacturing costs of the semiconductor device. In addition, the thickness of each part of the nanostructure layer 26 included in the first gate-all-around transistor in the length direction of the nanostructure layer 26 is less than the thickness of the corresponding nanostructure layer 26 included in the second gate-all-around transistor, so that a distance between each part of a bottom nanostructure layer 26 included in the first gate-all-around transistor in the length direction of the bottom nanostructure layer 26 and the semiconductor substrate 11 is greater than a distance between a bottom nanostructure layer 26 included in the second gate-all-around transistor and the semiconductor substrate 11. In a case that each of the first gate-all-around transistor and the second gate-all-around transistor includes at least two nanostructure layers 26, a distance between each part of one of two adjacent nanostructure layers 26 included in the first gate-all-around transistor in the length direction of the one of the two adjacent nanostructure layers 26 and each part of the other of the two adjacent nanostructure layers 26 in the length direction of the other of the two adjacent nanostructure layers 26 is greater than a distance between corresponding two adjacent nanostructure layers 26 included in the second gate-all-around transistor. In this case, even if the thickness of the gate stack 27 included in the first gate-all-around transistor is greater than the thickness of the gate stack 27 included in the second gate-all-around transistor, there will not be a problem where the distance between the bottom nanostructure layer in the first gate-all-around transistor and the semiconductor substrate and the distance between two adjacent nanostructure layers in the first gate-all-around transistor are too small due to the large thickness of the gate stack included in the first gate-all-around transistor, resulting in the subsequently formed gate electrode included in the first gate-all-around transistor cannot be filled or can only be partially filled. Moreover, the thickness of each part of the nanostructure layer 26 included in the first gate-all-around transistor in the length direction of the nanostructure layer 26 included in the first gate-all-around transistor is less than the thickness of the corresponding nanostructure layer 26 included in the second gate-all-around transistor, which may ensure that each part of the gate stack 27 included in the first gate-all-around transistor in the length direction of the gate stack 27 included in the first gate-all-around transistor may be properly filled in a void with higher height, thereby further ensuring that the gate electrode 29 included in the first gate-all-around transistor may have greater control ability over each part of the nanostructure layer 26 included in the first gate-all-around transistor in the length direction of the nanostructure layer 26 included in the first gate-all-around transistor, which is conducive to improving the operating performance of the semiconductor device.

In an example, as shown in FIG. 21A, the first gate-all-around transistor may further include an inner spacer for limiting a length of the gate stack 27 included in the first gate-all-around transistor. The inner spacer included in the first gate-all-around transistor is located between the gate stack 27 included in the first gate-all-around transistor and the source region 23 included in the first gate-all-around transistor, and between the gate stack 27 included in the first gate-all-around transistor and the drain region 24 included in the first gate-all-around transistor. A material of the inner spacer included in the first gate-all-around transistor may be an insulating material such as silicon nitride.

In an example, as shown in FIG. 21B, the second gate-all-around transistor may further include an inner spacer for limiting a length of the gate stack 27 included in the second gate-all-around transistor. The inner spacer included in the second gate-all-around transistor is located between the gate stack 27 included in the second gate-all-around transistor and the source region 23 included in the second gate-all-around transistor, and between the gate stack 27 included in the second gate-all-around transistor and the drain region 24 included in the second gate-all-around transistor. A material of the inner spacer included in the second gate-all-around transistor may be an insulating material such as silicon oxide or silicon nitride.

In a second aspect, embodiments of the present disclosure provide a method of manufacturing a semiconductor device. The manufacturing process will be described below based on cross-sectional views of operations shown in FIG. 1 to FIG. 22. For example, the method of manufacturing the semiconductor device includes the following steps.

A semiconductor substrate is provided. Specific structures and materials of the semiconductor substrate may be referred to the above and will not be repeated here.

Next, as shown in FIG. 21A and FIG. 21B and FIG. 22A and FIG. 22B, a first gate-all-around transistor and a second gate-all-around transistor are formed on the semiconductor substrate 11, and the first gate-all-around transistor and the second gate-all-around transistor are spaced apart from each other in a direction parallel to a surface of the semiconductor substrate 11. Each of the first gate-all-around transistor and the second gate-all-around transistor includes at least one nanostructure layer 26 between a source region 23 and a drain region 24. The nanostructure layer 26 included in the first gate-all-around transistor and the nanostructure layer 26 included in the second gate-all-around transistor are integrally formed. A thickness of each part of each nanostructure layer 26 included in the first gate-all-around transistor in a length direction of that nanostructure layer 26 is less than a thickness of a corresponding nanostructure layer 26 included in the second gate-all-around transistor. A thickness of a gate stack 27 included in the first gate-all-around transistor is greater than a thickness of the gate stack 27 included in the second gate-all-around transistor.

For example, specific structures and materials of the first gate-all-around transistor and the second gate-all-around transistor described above may be referred to the above and will not be repeated here. For example, forming, on the semiconductor substrate, a first gate-all-around transistor and a second gate-all-around transistor spaced apart from each other in a direction parallel to a surface of the semiconductor substrate may include the following steps.

As shown in FIG. 1, a stack of sacrificial layers 12 and channel layers 13 alternately arranged is formed on the semiconductor substrate 11. In the stack of sacrificial layers 12 and channel layers 13 alternately arranged, each of a film layer at a top of the stack of sacrificial layers 12 and channel layers 13 alternately arranged and a film layer at a bottom of the stack of sacrificial layers 12 and channel layers 13 alternately arranged is one of the sacrificial layers 12.

The above-described channel layers are used to manufacture the nanostructure layers included in the first gate-all-around transistor and the nanostructure layers included in the second gate-all-around transistor. Therefore, a material of each channel layer may refer to the material of each of the nanostructure layers included in the first gate-all-around transistor and the nanostructure layers included in the second gate-all-around transistor. The number of channel layers formed on the semiconductor substrate is equal to the number of nanostructure layers included in the first gate-all-around transistor and the number of nanostructure layers included in the second gate-all-around transistor. The thickness of each channel layer is equal to the thickness of the corresponding nanostructure layer in the second gate-all-around transistor.

As for the above-described sacrificial layer, a material of the sacrificial layer may be any semiconductor material different from the material of the channel layer. In addition, after removing the remaining part of each sacrificial layer in the second fin portion, a void between adjacent nanostructure layers and between the bottom nanostructure layer and the semiconductor substrate is formed and used for filling the gate stack included in the second gate-all-around transistor. Therefore, the thickness of the sacrificial layer may be determined by the thickness of the gate stack included in the second gate-all-around transistor.

In the practical manufacturing process, the above-described stack of sacrificial layers and channel layers alternately arranged may be formed by using processes such as epitaxial growth.

Next, as shown in FIG. 2, the stack of sacrificial layers and channel layers alternately arranged are patterned to form a first fin portion 14 and a second fin portion 15 spaced apart from each other on the semiconductor substrate 11.

In the practical manufacturing process, the stack of the sacrificial layers and the channel layers alternately arranged and part of the semiconductor substrate may be patterned by processes such as photolithography and etching, so as to form a first fin structure and a second fin structure spaced apart from each other on the semiconductor substrate. Then, as shown in FIG. 2, a shallow trench isolation 16 may be formed on the semiconductor substrate 11 by processes such as deposition and etching. The top of the shallow trench isolation 16 is lower in height than the bottom of the sacrificial layer 12 in each of the first fin structure and the second fin structure. A part of the first fin structure and a part of the second fin structure exposed outside the shallow trench isolation 16 are the first fin portion 14 and the second fin portion 15, respectively.

Next, as shown in FIG. 3, a sacrificial gate 17 and a gate spacer 18 spanning across each of the first fin portion 14 and the second fin portion 15 are sequentially formed. The gate spacer 18 is located at least on two sides of the sacrificial gate 17 in a length direction of the sacrificial gate 17.

In the practical manufacturing process, the sacrificial gate and the gate spacer described above may be sequentially formed by processes such as deposition and etching. A material of the sacrificial gate may be an easily removable material such as polycrystalline silicon, and a material of the gate spacer may be an insulating material such as silicon oxide, silicon nitride or silicon oxynitride.

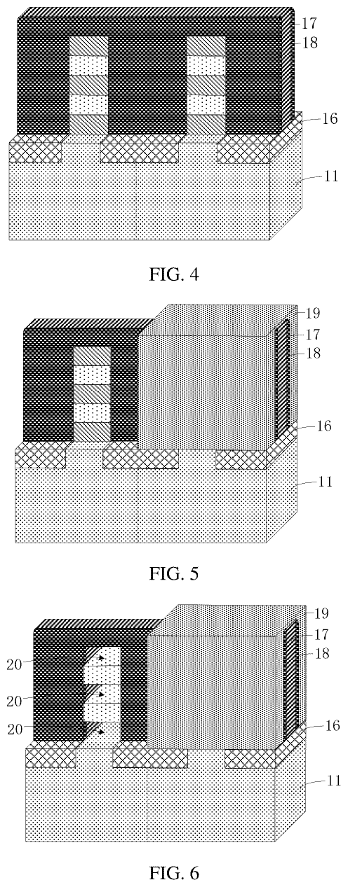

Then, as shown in FIG. 4, the first fin portion and the second fin portion may be etched by dry etching or wet etching by using the sacrificial gate 17 and the gate spacer 18 as a mask. At this point, two sides of the first fin portion in the length direction of the first fin portion are exposed, and two sides of the second fin portion in the length direction of the second fin portion are exposed.

Next, as shown in FIG. 6, a remaining part of each of the sacrificial layers in the first fin portion is removed by using a mask layer 19 as a mask. As shown in FIG. 8 to FIG. 13, a remaining part of each of the channel layers in the first fin portion is thinned to form a dielectric layer 21 filled in a void 20. The void 20 is located between the remaining part of each of the channel layers in the first fin portion and an adjacent structure. The adjacent structure is at least one of the semiconductor substrate 11, the remaining part of a channel layer adjacent to the each of the channel layers in the first fin portion, or the sacrificial gate 17. The mask layer 19 covers a remaining part of the second fin portion.

In the practical manufacturing process, as shown in FIG. 5, a mask layer 19 that only covers the remaining part of the second fin portion is formed by processes such as deposition and etching. A top of the mask layer 19 may be flush with a top of the sacrificial gate 17, or may also be higher than the top of the sacrificial gate 17. In addition, a material of the mask layer 19 may be silicon nitride, silicon oxide, silicon oxynitride, aluminum oxide, or titanium oxide, etc. After forming the mask layer 19, only the remaining part of the sacrificial layer and the remaining part of the channel layer included in the first fin portion are exposed, while the remaining part of the sacrificial layer and the remaining part of the channel layer included in the second fin portion are covered by the mask layer 19. In this case, as shown in FIG. 6 and FIG. 7, the remaining part of each sacrificial layer 12 in the first fin portion may be selectively removed by processes such as dry etching or wet etching. At this point, two sides of each channel layer 13 remaining in the first fin portion in the length direction of that channel layer 13 and two sides of each channel layer 13 remaining in the first fin portion in the thickness direction of that channel layer 13 are exposed, while two sides of each channel layer 13 remaining in the first fin portion in the width direction of that channel layer 13 are covered by the sacrificial gate 17 and the gate spacer 18. As for the void 20 and adjacent structures described above, as shown in FIG. 6 and FIG. 7, taking the first fin portion including two channel layers as an example, for the bottom channel layer remaining in the first fin portion, structures adjacent to the bottom channel layer remaining in the first fin portion are the semiconductor substrate 11 and a second channel layer remaining in the first fin portion. For the second channel layer remaining in the first fin portion, structures adjacent to the second channel layer remaining in the first fin portion are the bottom channel layer remaining in the first fin portion and the sacrificial gate 17. Next, as shown in FIG. 8 to FIG. 13, the remaining part of each channel layer in the first fin portion may be thinned by processes such as thermal oxidation process, and a dielectric layer 21 with at least a thickness may be formed. For example, when performing the remaining part of each channel layer in the first fin portion by thermal oxidation process, oxygen reacts with each channel layer remaining in the first fin portion, so as to not only form the dielectric layer 21 with at least a thickness on the remaining part of each channel layer in the first fin portion, but also consume part of the thickness of each channel layer remaining in the first fin portion, thereby thinning each channel layer remaining in the first fin portion.

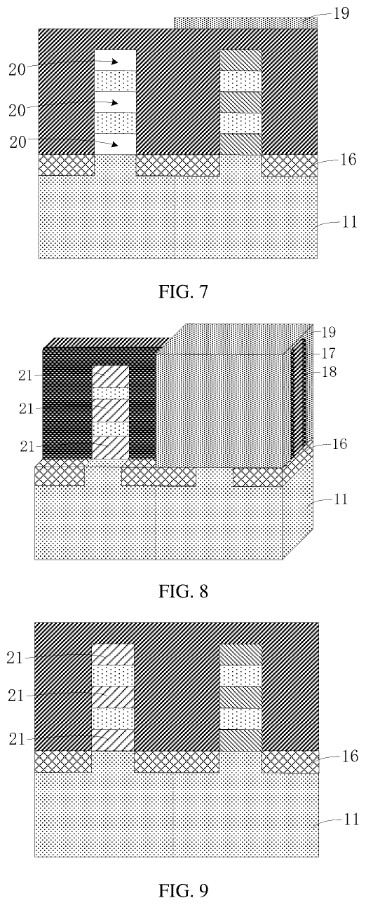

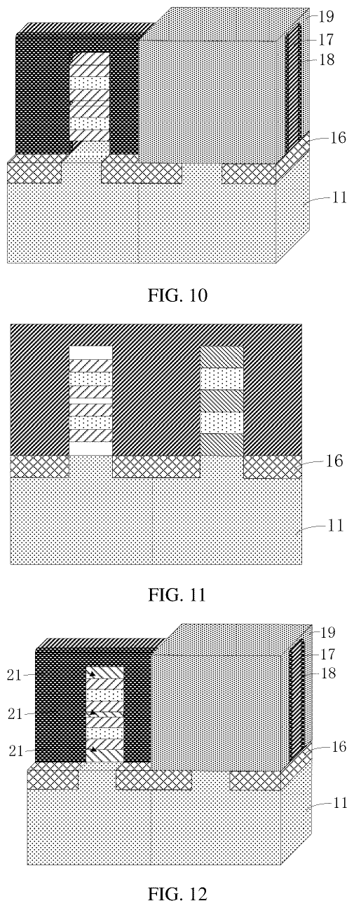

As shown in FIG. 8 and FIG. 9, the above-described dielectric layer 21 may be formed by thermal oxidation process. Alternatively, as shown in FIG. 10 to FIG. 13, the dielectric layer 21 with at least a thickness may be formed by thermal oxidation process, and then the remaining part of the dielectric layer 21 may be formed by atomic layer deposition process. In the above case, it may be understood that, the part of the thickness of each channel layer remaining in the first fin portion will not be consumed when forming the remaining part of the dielectric layer 21 by atomic layer deposition process. Therefore, compared with the dielectric layer 21 formed jointly by thermal oxidation process and atomic layer deposition process, when the dielectric layer 21 is formed entirely by thermal oxidation process, the thickness of each channel layer remaining in the first fin after thinning is less, which is more conducive to forming a gate stack 27 with a larger thickness. Compared with the dielectric layer 21 formed entirely by thermal oxidation process, when the dielectric layer 21 is formed jointly by thermal oxidation process and atomic layer deposition process, a length consumption of each channel layer remaining in the first fin portion after thinning will be smaller, that is, the length of each channel layer remaining in the first fin portion after thinning will be larger, which may ensure that the length of the nanostructure layer 26 included in the first gate-all-around transistor and the length of the nanostructure layer 26 included in the second gate-all-around transistor may meet the operating requirements.

Furthermore, it should be noted that when the dielectric layer is formed jointly by thermal oxidation process and atomic layer deposition process, the material of the part of the dielectric layer formed by thermal oxidation process may be the same as the material of the part of the dielectric layer formed by atomic layer deposition process; alternatively, the material of the part of the dielectric layer formed by thermal oxidation process may be different from the material of the part of the dielectric layer formed by atomic layer deposition process. For example, in the dielectric layer, the material of the part of the dielectric layer formed by thermal oxidation process is silicon oxide, and the material of the part of the dielectric layer formed by atomic layer deposition process may be silicon oxide or silicon nitride, etc.

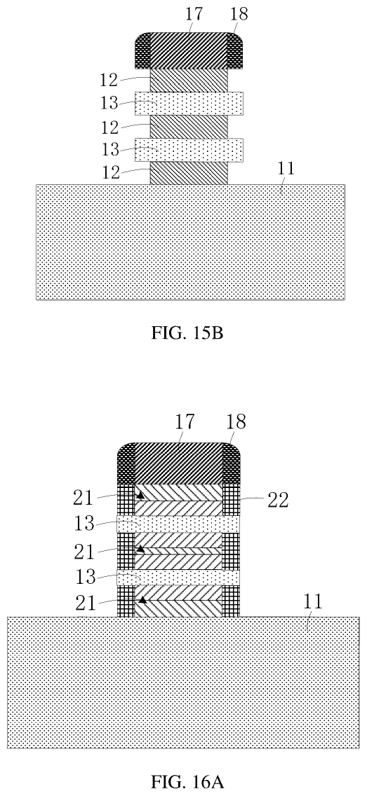

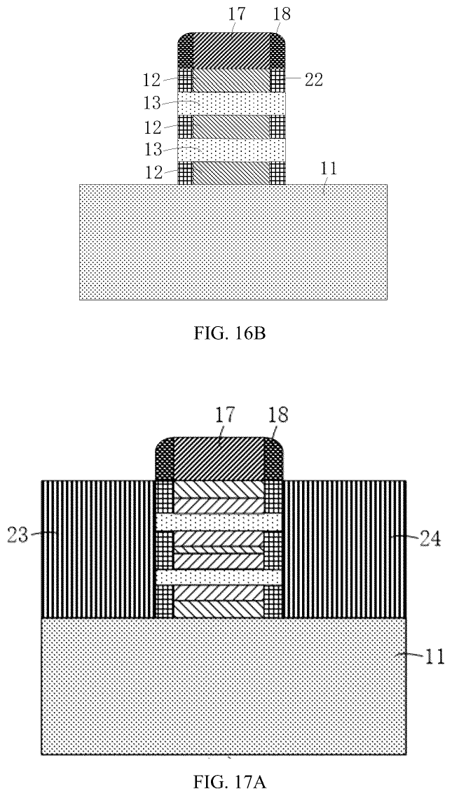

For example, as shown in FIG. 21A and FIG. 22A, in the case that the manufactured first gate-all-around transistor further includes an inner spacer, after forming the dielectric layer filled in the void, the method of manufacturing the semiconductor device further includes following steps. As shown in FIG. 15A, edge parts of the dielectric layer 21 on two sides of the dielectric layer 21 in the length direction of the sacrificial gate 17 are removed by processes such as dry etching or wet etching, so that a sidewall of a remaining part of the dielectric layer 21 is recessed inward relative to a sidewall of the remaining part of each channel layer 13 in the first fin portion. As shown in FIG. 16A, an inner spacer 22 filled on two sides of the remaining part of the dielectric layer 21 in the length direction of the sacrificial gate 17 is formed by processes such as deposition and etching. The material of the inner spacer 22 may refer to the above.

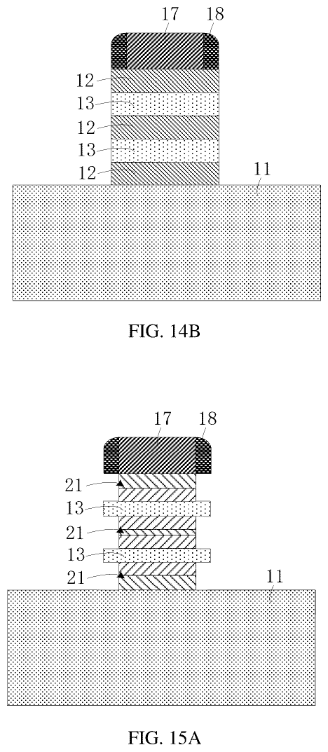

Next, as shown in FIG. 14A and FIG. 14B, the mask layer may be removed by processes such as dry etching or wet etching.

In the case that the first gate-all-around transistor further includes the inner spacer, embodiments of the present disclosure do not specifically limit the order of removing the mask layer. The mask layer may be removed after forming the inner spacer included in the first gate-all-around transistor. Alternatively, the mask layer may be removed after forming the dielectric layer and before forming the inner spacer.

For example, as shown in FIG. 21B and FIG. 22B, in the case that the manufactured first gate-all-around transistor further includes the inner spacer, the method of manufacturing the semiconductor device further includes the following steps: after removing the mask layer and before performing subsequent operations, as shown in FIG. 15B, edge parts of each sacrificial layer 12 remaining in the second fin portion on two sides of that sacrificial layer 12 in the length direction of the sacrificial gate 17 may be removed by processes such as dry etching or wet etching, so that a sidewall of the remaining part of each sacrificial layer 12 in the second fin portion is recessed inward relative to a sidewall of each channel layer 13 remaining in the second fin portion. Then, as shown in FIG. 16B, an inner spacer 22 filled on two sides of the remaining part of each sacrificial layer 12 in the second fin portion in the length direction of the sacrificial gate 17 is formed by processes such as dry etching or wet etching. A material of the inner spacer 22 may refer to the above.

Next, as shown in FIG. 17A and FIG. 17B, a source region 23 included in the first gate-all-around transistor and a drain region 24 included in the first gate-all-around transistor are formed on two sides of the remaining part of the first fin portion in the length direction of the remaining part of the first fin portion by processes such as epitaxial growth, and a source region 23 included in the second gate-all-around transistor and a drain region 24 included in the second gate-all-around transistor are formed on two sides of the remaining part of the second fin portion in the length direction of the remaining part of the second fin portion.

It should be noted that when the conductivity type of the first gate-all-around transistor is different from the conductivity type of the second gate-all-around transistor, the source region and the drain region included in one of the first gate-all-around transistor and the second gate-all-around transistor may be formed by processes such as epitaxy by using the corresponding mask layer as a mask, and then the source region and the drain region included in the other one of the first gate-all-around transistor and the second gate-all-around transistor may be formed. Next, the corresponding mask layer may be removed by processes such as dry etching or wet etching.

When the conductivity type of the first gate-all-around transistor is the same as the conductivity type of the second gate-all-around transistor, the source region and the drain region included in the first gate-all-around transistor and the source region and the drain region included in the second gate-all-around transistor may be formed in the same step. Alternatively, the source region and the drain region included in the first gate-all-around transistor and the source region and the drain region included in the second gate-all-around transistor may be formed in different steps.

It is worth noting that, in the manufacturing method provided by embodiments of the present disclosure, each channel layer remaining in the first fin portion is thinned before forming the source region and the drain region included in the first gate-all-around transistor and the source region and the drain region included in the second gate-all-around transistor, so that the thickness of each part of the nanostructure layer formed based on the remaining part of each channel layer in the first fin portion in the length direction of the the nanostructure layer is less than the thickness of the nanostructure layer formed based on the remaining part of the corresponding channel layer in the second fin portion, thereby preventing more impurities in the source region and the drain region caused by high temperature of thinning process from spreading into the nanostructure layer, and restraining short channel effects of the first gate-all-around transistor and the second gate-all-around transistor.

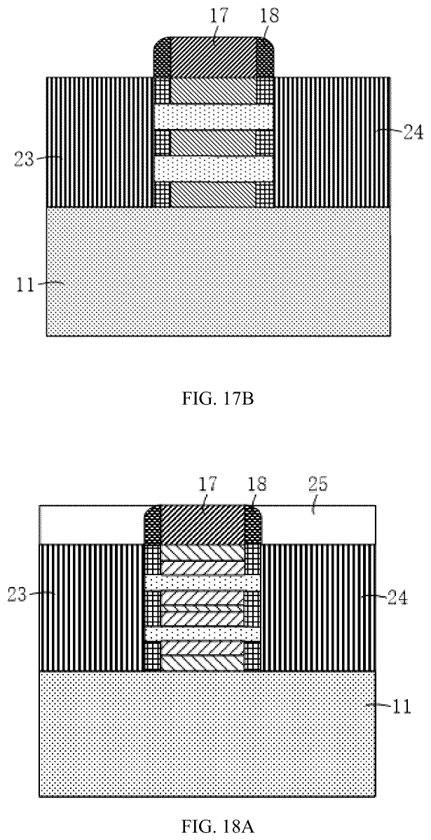

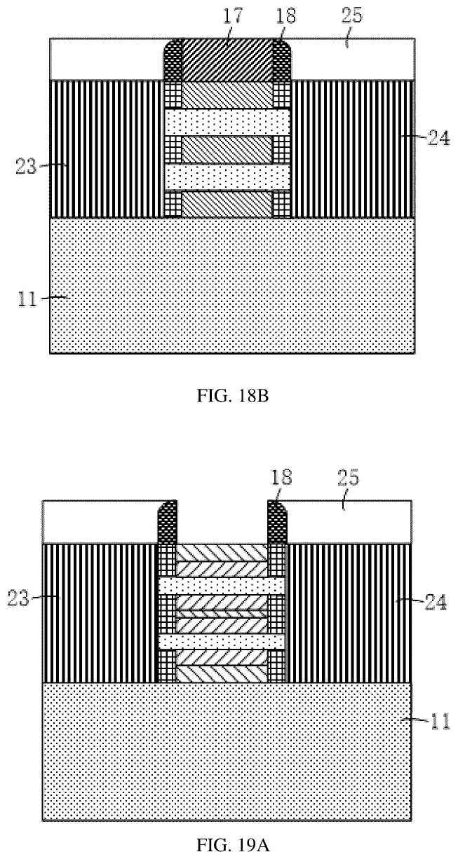

Next, as shown in FIG. 18A and FIG. 18B, an interlayer dielectric layer 25 covering the formed structure may be formed by processes such as deposition and chemical mechanical polishing. A top of the interlayer dielectric layer 25 is flush with a top of the sacrificial gate 17, and a material of the interlayer dielectric layer 25 may be an insulating material such as silicon oxide.

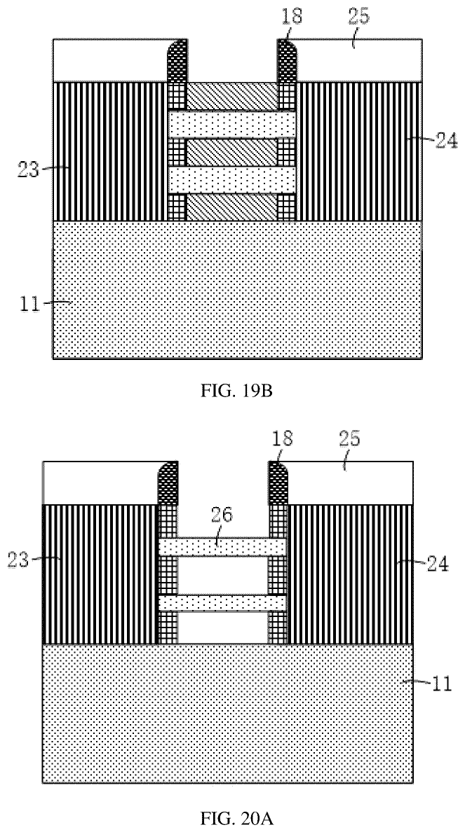

Then, as shown in FIG. 19A and FIG. 19B, the sacrificial gate may be removed by processes such as dry etching or wet etching.

Next, as shown in FIG. 20A and FIG. 20B, the dielectric layer may be removed by processes such as dry etching or wet etching, so that the remaining part of each channel layer in the first fin portion forms the corresponding nanostructure layer 26 in the first gate-all-around transistor, and the remaining part of each sacrificial layer in the second fin portion may be removed, so that the remaining part of each channel layer in the second fin portion forms the corresponding nanostructure layer 26 in the second gate-all-around transistor.

Then, as shown in FIG. 21A and FIG. 21B, the gate stack 27 included in the first gate-all-around transistor and the gate stack 27 included in the second gate-all-around transistor are formed by processes such as atomic layer deposition.

In the practical manufacturing process, the gate stack included in the first gate-all-around transistor may be formed by using the corresponding mask layer as a mask. Next, after removing the mask layer, a gate stack included in the second gate-all-around transistor is formed. Alternatively, an order of forming the gate stack included in the first gate-all-around transistor and an order of forming the gate stack included in the second gate-all-around transistor may be exchanged.

Alternatively, when the material of the gate dielectric layer included in the second gate-all-around transistor is the same as that of at least part of the gate dielectric layer included in the first gate-all-around transistor, and the material of the gate electrode included in the first gate-all-around transistor is the same as that of the gate electrode included in the second gate-all-around transistor, corresponding materials and corresponding thicknesses of gate dielectric materials may be formed only on the periphery of at least part of the nanostructure layer included in the first gate-all-around transistor by using the corresponding mask layer as a mask, and then the corresponding mask layer is removed, while forming the gate electrode and the remaining part of the gate dielectric layer included in the first gate-all-around transistor, and the gate electrode and the gate dielectric layer included in the second gate-all-around transistor.

It should be noted that the gate dielectric layer included in the first gate-all-around transistor may be formed by sequentially using thermal oxidation process and atomic layer deposition process. At this point, as shown in FIG. 22A, after forming the gate dielectric layer 28 included in the first gate-all-around transistor, the thickness of the part of each nanostructure layer 26 in the first gate-all-around transistor surrounded by the gate dielectric layer 28 is less than the thickness of the remaining part of that nanostructure layer 26 in the first gate-all-around transistor. Alternatively, the gate dielectric layer 28 included in the first gate-all-around transistor may be formed by a process such as atomic layer deposition process that does not consume the nanostructure layer 26 in the first gate-all-around transistor. As shown in FIG. 21A, after forming the gate dielectric layer 28 included in the first gate-all-around transistor, the thickness of each part of each nanostructure layer 26 in the first gate-all-around transistor in the length direction of the nanostructure layer 26 in the first gate-all-around transistor is the same.

In addition, the gate stack included in the first gate-all-around transistor and the gate stack included in the second gate-all-around transistor may be formed in various methods. How to form the gate stack included in the first gate-all-around transistor and the gate stack included in the second gate-all-around transistor described above is not a main portion of the present disclosure. Therefore, in the present disclosure, only a brief introduction is provided to facilitate the implementation of the present disclosure by those skilled in the art. Those skilled in the art may completely imagine other methods to manufacture the gate stack included in the first gate-all-around transistor and the gate stack included in the second gate-all-around transistor described above.

The beneficial effects of the second aspect in embodiments of the present disclosure and various embodiments of the second aspect in the embodiments of the present disclosure may be referred to the analysis of the beneficial effects of the first aspect in embodiments of the present disclosure and various embodiments of the first aspect in the embodiments of the present disclosure, which will not be repeated here.

In the above description, there is no detailed explanation of technical details such as patterning or etching of each layer. However, those skilled in the art should understand that layers, regions, etc. of the desired shape may be formed through various technical means. In addition, in order to form the same structure, those skilled in the art may also design methods that are not exactly the same as the methods described above. Furthermore, although each embodiment is described separately above, this does not mean that the measures in various embodiments cannot be advantageously combined.

The above describes embodiments of the present disclosure. However, these embodiments are for illustrative purposes only and are not intended to limit the scope of the present disclosure. The scope of the present disclosure is limited by the attached claims and their equivalents. Without departing from the scope of the present disclosure, those skilled in the art may make various substitutions and modifications, all of which should fall within the scope of the present disclosure.

What is claimed is:

1. A semiconductor device, comprising:
a semiconductor substrate; and
a first gate-all-around transistor and a second gate-all-around transistor formed on the semiconductor substrate and spaced apart from each other in a direction parallel to a surface of the semiconductor substrate,
wherein each of the first gate-all-around transistor and the second gate-all-around transistor comprises at least one nanostructure layer between a source region and a drain region, the nanostructure layer comprised in the first gate-all-around transistor and the nanostructure layer comprised in the second gate-all-around transistor are integrally formed, a thickness of each part of each nanostructure layer of the at least one nanostructure layer comprised in the first gate-all-around transistor in a length direction of the nanostructure layer comprised in the first gate-all-around transistor is less than a thickness of a corresponding nanostructure layer comprised in the second gate-all-around transistor, and a thickness of a gate stack comprised in the first gate-all-around transistor is greater than a thickness of a gate stack comprised in the second gate-all-around transistor.

2. The semiconductor device of claim 1, wherein the thickness of each part of each nanostructure layer of the at least one nanostructure layer comprised in the first gate-all-around transistor in the length direction of the nanostructure layer comprised in the first gate-all-around transistor is the same.

3. The semiconductor device of claim 1, wherein a thickness of a middle part of each nanostructure layer of the at least one nanostructure layer comprised in the first gate-all-around transistor in the length direction of the nanostructure layer comprised in the first gate-all-around transistor is less than a thickness of each of edge parts of the nanostructure layer on two sides of the nanostructure layer comprised in the first gate-all-around transistor.

4. The semiconductor device of claim 1, wherein a width of the nanostructure layer comprised in the first gate-all-around transistor is equal to a width of the nanostructure layer comprised in the second gate-all-around transistor.

5. The semiconductor device of claim 1, wherein the first gate-all-around transistor further comprises an inner spacer between the gate stack comprised in the first gate-all-around transistor and the source region comprised in the first gate-all-around transistor, and between the gate stack comprised in the first gate-all-around transistor and the drain region comprised in the first gate-all-around transistor.

6. The semiconductor device of claim 1, wherein the second gate-all-around transistor further comprises an inner spacer between the gate stack comprised in the second gate-all-around transistor and the source region comprised in the second gate-all-around transistor, and between the gate stack comprised in the second gate-all-around transistor and the drain region comprised in the second gate-all-around transistor.

7. The semiconductor device of claim 5, wherein the second gate-all-around transistor further comprises an inner spacer between the gate stack comprised in the second gate-all-around transistor and the source region comprised in the second gate-all-around transistor, and between the gate stack comprised in the second gate-all-around transistor and the drain region comprised in the second gate-all-around transistor.

8. The semiconductor device of claim 1, wherein the first gate-all-around transistor is an input/output gate-all-around transistor, and a thickness of a gate dielectric layer comprised in the first gate-all-around transistor is greater than a thickness of a gate dielectric layer comprised in the second gate-all-around transistor.

9. The semiconductor device of claim 2, wherein the first gate-all-around transistor is an input/output gate-all-around transistor, and a thickness of a gate dielectric layer comprised in the first gate-all-around transistor is greater than a thickness of a gate dielectric layer comprised in the second gate-all-around transistor.

10. The semiconductor device of claim 4, wherein the first gate-all-around transistor is an input/output gate-all-around transistor, and a thickness of a gate dielectric layer comprised in the first gate-all-around transistor is greater than a thickness of a gate dielectric layer comprised in the second gate-all-around transistor.

11. The semiconductor device of claim 5, wherein the first gate-all-around transistor is an input/output gate-all-around transistor, and a thickness of a gate dielectric layer comprised in the first gate-all-around transistor is greater than a thickness of a gate dielectric layer comprised in the second gate-all-around transistor.

12. A method of manufacturing a semiconductor device, comprising:
providing a semiconductor substrate; and
forming, on the semiconductor substrate, a first gate-all-around transistor and a second gate-all-around transistor spaced apart from each other in a direction parallel to a surface of the semiconductor substrate,
wherein each of the first gate-all-around transistor and the second gate-all-around transistor comprises at least one nanostructure layer between a source region and a drain region, the nanostructure layer comprised in the first gate-all-around transistor and the nanostructure layer comprised in the second gate-all-around transistor are integrally formed, a thickness of each part of each nanostructure layer of the at least one nanostructure layer comprised in the first gate-all-around transistor in a length direction of the nanostructure layer comprised in the first gate-all-around transistor is less than a thickness of a corresponding nanostructure layer comprised in the second gate-all-around transistor, and a thickness of a gate stack comprised in the first gate-all-around transistor is greater than a thickness of a gate stack comprised in the second gate-all-around transistor.

13. The method of claim 12, wherein the forming, on the semiconductor substrate, a first gate-all-around transistor and a second gate-all-around transistor spaced apart from each other in a direction parallel to a surface of the semiconductor substrate comprises:
forming a stack of sacrificial layers and at least one channel layer alternately arranged on the semiconductor substrate, wherein each of a film layer at a top of the stack of sacrificial layers and at least one channel layer alternately arranged and a film layer at a bottom of the stack of sacrificial layers and at least one channel layer alternately arranged is one of the sacrificial layers;
patterning the stack of the sacrificial layers and the at least one channel layer alternately arranged to form a first fin portion and a second fin portion spaced apart from each other on the semiconductor substrate;
sequentially forming a sacrificial gate and a gate spacer spanning across each of the first fin portion and the second fin portion, wherein the gate spacer is located at least on two sides of the sacrificial gate in a length direction of the sacrificial gate;
etching the first fin portion and the second fin portion by using the sacrificial gate and the gate spacer as a mask;
removing a remaining part of each of the sacrificial layers in the first fin portion by using a mask layer as a mask; thinning a remaining part of each of the at least one channel layer in the first fin portion; forming a dielectric layer filled in a void formed between the remaining part of each of the at least one channel layer in the first fin portion and an adjacent structure, wherein the adjacent structure is at least one of the semiconductor substrate, the remaining part of a channel layer adjacent to the each of the at least one channel layer in the first fin portion, or the sacrificial gate, and wherein the mask layer covers a remaining part of the second fin portion;
removing the mask layer;
forming the source region comprised in the first gate-all-around transistor and the drain region comprised in the first gate-all-around transistor on two sides of a remaining part of the first fin portion in a length direction of the first fin portion; and forming the source region comprised in the second gate-all-around transistor and the drain region comprised in the second gate-all-around transistor on two sides of the remaining part of the second fin portion in a length direction of the second fin portion;
removing the sacrificial gate;
removing the dielectric layer, so that the remaining part of each of the at least one channel layer in the first fin portion forms a corresponding nanostructure layer in the first gate-all-around transistor; and removing the remaining part of each of the sacrificial layers in the second fin portion, so that the remaining part of each of the at least one channel layer in the second fin portion forms a corresponding nanostructure layer in the second gate-all-around transistor.

14. The method of claim 13, further comprising:
thinning the remaining part of each of the at least one channel layer in the first fin portion by a thermal oxidation process; and forming the dielectric layer with at least a thickness.

15. The method of claim 14, further comprising:
forming the dielectric layer by sequentially using the thermal oxidation process and an atomic layer deposition process,
wherein a material of a part of the dielectric layer formed by using the thermal oxidation process is the same as a material of a part of the dielectric layer formed by using the atomic layer deposition process; or a material of a part of the dielectric layer formed by using the thermal oxidation process is different from a material of a part of the dielectric layer formed by using the atomic layer deposition process.

16. The method of claim 13, further comprising: after forming the dielectric layer filled in the void, and before forming the source region comprised in the first gate-all-around transistor and the drain region comprised in the first gate-all-around transistor on two sides of the remaining part of the first fin portion in the length direction of the first gate-all-around,
removing edge parts of the dielectric layer on two sides of the dielectric layer in the length direction of the sacrificial gate, so that a sidewall of a remaining part of the dielectric layer is recessed inward relative to a sidewall of the remaining part of each of the at least one channel layer in the first fin portion; and forming an inner spacer filled on two sides of the remaining part of the dielectric layer in the length direction of the sacrificial gate.

17. The method of claim 13, further comprising: after removing the mask layer and before forming the source region comprised in the second gate-all-around transistor and the drain region comprised in the second gate-all-around transistor on two sides of the remaining part of the second fin portion in the length direction of the second fin portion,
removing edge parts of each sacrificial layer on two sides of the each sacrificial layer remaining in the second fin portion in the length direction of the sacrificial gate, so that a sidewall of a remaining part of each sacrificial layer in the second fin portion is recessed inward relative to a sidewall of each channel layer remaining in the second fin portion; and forming an inner spacer filled on two sides of the remaining part of each sacrificial layer in the second fin portion in the length direction of the sacrificial gate.

18. The method of claim 16, further comprising: after removing the mask layer and before forming the source region comprised in the second gate-all-around transistor and the drain region comprised in the second gate-all-around transistor on two sides of the remaining part of the second fin portion in the length direction of the second fin portion,
removing edge parts of each sacrificial layer on two sides of the each sacrificial layer remaining in the second fin portion in the length direction of the sacrificial gate, so that a sidewall of a remaining part of each sacrificial layer in the second fin portion is recessed inward relative to a sidewall of each channel layer remaining in the second fin portion; and forming an inner spacer filled on two sides of the remaining part of each sacrificial layer in the second fin portion in the length direction of the sacrificial gate.

19. The method of claim 14, further comprising: after forming the dielectric layer filled in the void, and before forming the source region comprised in the first gate-all-around transistor and the drain region comprised in the first gate-all-around transistor on two sides of the remaining part of the first fin portion in the length direction of the first gate-all-around,
removing edge parts of the dielectric layer on two sides of the dielectric layer in the length direction of the sacrificial gate, so that a sidewall of a remaining part of the dielectric layer is recessed inward relative to a sidewall of the remaining part of each of the at least one channel layer in the first fin portion; and forming an inner spacer filled on two sides of the remaining part of the dielectric layer in the length direction of the sacrificial gate; and/or
the method further comprising: after removing the mask layer and before forming the source region comprised in the second gate-all-around transistor and the drain region comprised in the second gate-all-around transistor on two sides of the remaining part of the second fin portion in the length direction of the second fin portion,
removing edge parts of each sacrificial layer on two sides of the each sacrificial layer remaining in the second fin portion in the length direction of the sacrificial gate, so that a sidewall of a remaining part of each sacrificial layer in the second fin portion is recessed inward relative to a sidewall of each channel layer remaining in the second fin portion; and forming an inner spacer filled on two sides of the remaining part of each sacrificial layer in the second fin portion in the length direction of the sacrificial gate.

20. The method of claim 15, further comprising: after forming the dielectric layer filled in the void, and before forming the source region comprised in the first gate-all-around transistor and the drain region comprised in the first gate-all-around transistor on two sides of the remaining part of the first fin portion in the length direction of the first gate-all-around,
removing edge parts of the dielectric layer on two sides of the dielectric layer in the length direction of the sacrificial gate, so that a sidewall of a remaining part of the dielectric layer is recessed inward relative to a sidewall of the remaining part of each of the at least one channel layer in the first fin portion; and forming an inner spacer filled on two sides of the remaining part of the dielectric layer in the length direction of the sacrificial gate; and/or
the method further comprising: after removing the mask layer and before forming the source region comprised in the second gate-all-around transistor and the drain region comprised in the second gate-all-around transistor on two sides of the remaining part of the second fin portion in the length direction of the second fin portion,
removing edge parts of each sacrificial layer on two sides of the each sacrificial layer remaining in the second fin portion in the length direction of the sacrificial gate, so that a sidewall of a remaining part of each sacrificial layer in the second fin portion is recessed inward relative to a sidewall of each channel layer remaining in the second fin portion; and forming an inner spacer filled on two sides of the remaining part of each sacrificial layer in the second fin portion in the length direction of the sacrificial gate.
